(19) United States
(12) Patent Application Publication
(10) Pub. No.: US 2007/0164754 A1
(43) Pub. Date: Jul. 19, 2007

(54) On-chip high frequency power supply noise sensor

(75) Inventors: George E. Smith III, Wappingers Falls, NY (US); Michael A. Sperling, Poughkeepsie, NY (US)

Correspondence Address: Lynn L. Augspurger;IBM Corporation, 2455 South Road, P386, Poughkeepsie, NY, 12601, US

(73) Assignee: International Business Machines Corporation, Armonk, NY (US)

(21) Appl. No.: 11/334,279

(22) Filed: Jan. 18, 2006

(51) Int. Cl. G01R 29/26

(52) U.S. Cl. 324/613

(57) ABSTRACT

The lower power on-chip power supply noise sensor detects high frequency overshoots and undershoots of the power supply voltage. The sensor has two resistor chains that span the full power rail, with a reactive element to form a low pass filter as part of one of the resistor chains. By this expedient the high frequency transient behavior differs between the two chains, while the low frequency behavior is equivalent. This allows a voltage comparison to be made with comparators. The comparator output can be latched or transmitted as a sampling signal.

### BACKGROUND

1. Field of the Invention

The invention relates to non-invasive, on-chip detection of power supply noise that is beyond the control of off-chip power supply feedback. The noise is of the type characterized as over shoot, and is constrained by a maximum allowed level and a minimum allowed level, and is controllable, e.g., by limiting, clipping, or clamping to lessen or eliminate intermittent spuriously generated components from a signal.

2. Background Art

Integrated circuits are highly susceptible to upsets arising from excursions in the output of on-chip power supplies. One problem area is managing high frequency power supply noise that is beyond the control of off-chip power supply feedback.

### SUMMARY OF THE INVENTION

The system described herein manages high frequency power supply noise that is beyond the control of off-chip power supply feedback. The on-chip power supply noise sensor detects high frequency overshoots and undershoots of the power supply voltage.

The sensor has two resistor chains that span the full power rail, with a reactive element to form a low pass filter or time constant circuit, as part of one of the resistor chains. By this expedient the high frequency transient behavior differs between the two chains, while the low frequency behavior is equivalent. This allows a voltage comparison to be made, for example with comparators. The comparator output can be latched or transmitted as a sampling signal.

### THE FIGURES

Various aspects of our invention are illustrated in the Figures appended hereto.

FIG. 1 shows a high level representation of noise sensor with two resistor chains, one of which has a reactive element in parallel with a segment of one of the resistor chains to form a low pass filter.

FIG. 2 shows a more detailed representation of a noise sensor with two resistor chains, one of which has a reactive element in parallel and with a segment of one of the resistor chains to thereby form a low pass filter.

### DETAILED DESCRIPTION OF THE INVENTION

The system of our invention manages high frequency power supply noise that is beyond the control of off-chip power supply feedback. The lower power on-chip power supply noise sensor detects high frequency overshoots and undershoots of the power supply voltage. The sensor has two resistor chains. These chains span the full power rail from input to ground. One resistor chain has a reactive element to thereby form a low pass filter, as part of one of the resistor chains. By this expedient the high frequency transient behavior differs between the two chains, while the low frequency behavior is equivalent between the chains. This allows a voltage comparison to be made, for example with comparators. The comparator output can be latched or transmitted as a sampling signal, for example to trigger a reset.

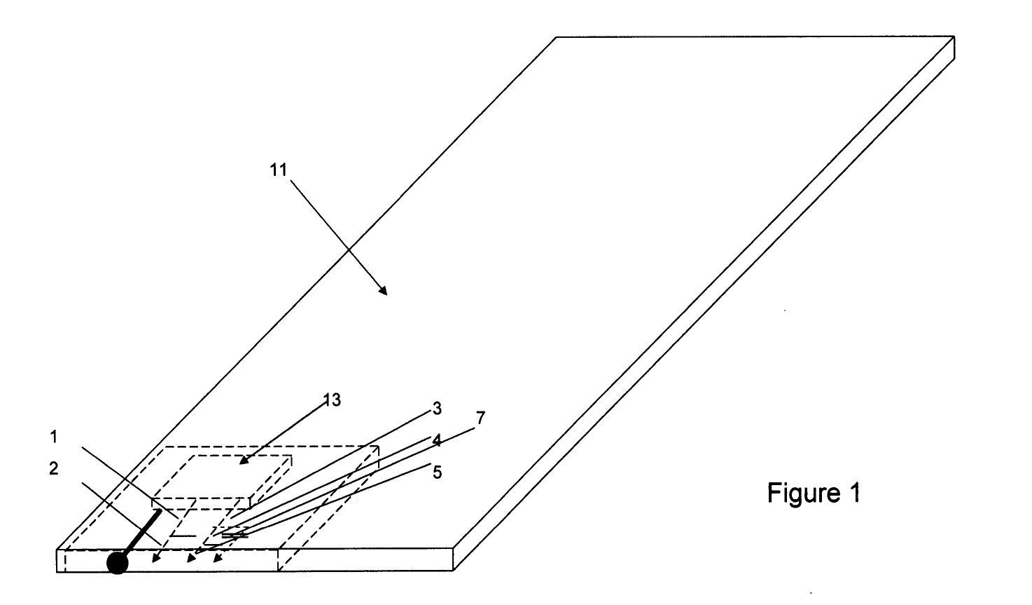

FIG. 1 is a perspective of a integrated circuit chip 11 containing a power supply noise sensor 13 of the invention. The power supply noise sensor 13 includes a resistor pair 1, 2 with an outlet to ground, and a resistor chain 3,4,5 in parallel with a capacitor 7, to form a low pass filter.

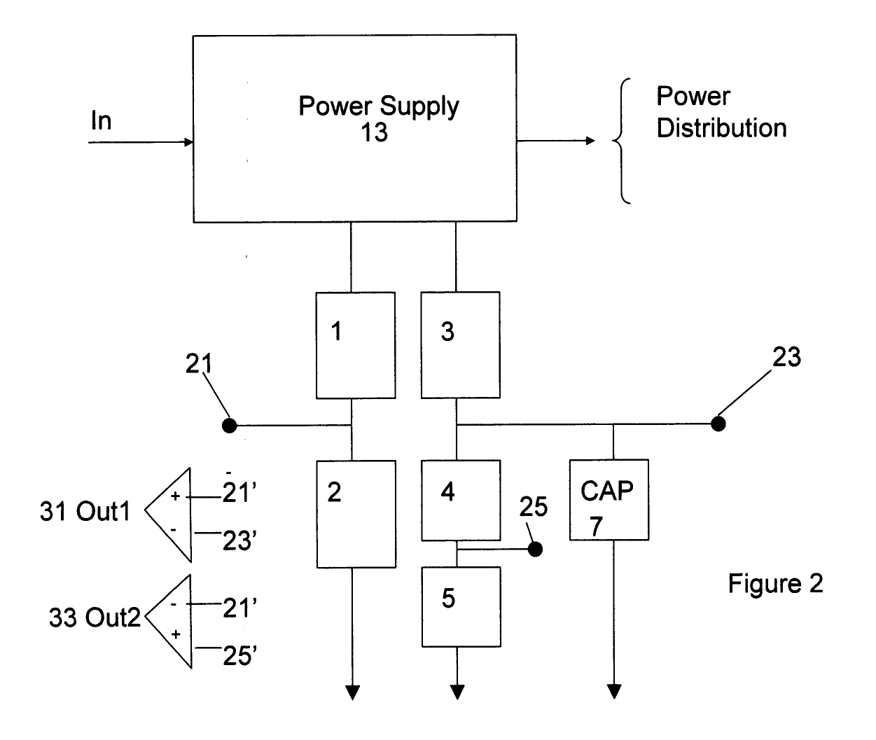

FIG. 2 shows a noise sensor with two resistor chains, one of which has a reactive element in parallel with a segment of one of the resistor chains. With resistors 1 and 2 connected in series from the power supply to ground, the voltage on node 21 responds immediately to any power supply deviation. The resistors 3, 4, and 5 form a second resistor chain with capacitor 7 forming a low pass filter that holds the voltage at node 23 steady during high frequency power supply deviations. Node 25 is also an extra output that is also constant during high frequency noise events.

The on-chip noise sensor has a pair of comparators, where one of the comparators has a plus input 21′ from a tap 21 on the resistor chain 1,2 and a minus input 23′ from the tap 23 on the capacitor 7. The other capacitor has a plus input 25′ from the low pass filter tap 25 between the capacitor 7 and ground, and a minus input 21′ from a tap 21 on the resistor chain 2, 1.

By comparing the voltage on node 21 with the voltages on nodes 23, and 25 it is possible to generate a digital signal. This digital signal can be used to set a latch or as a sampling signal to inform other circuitry that there was a large magnitude noise event in the system.

This allows testing multiple thresholds by tapping off of different points on the second resistor chain, that is between Node 23 and ground. For example, in FIG. 2, if all of the resistors are assumed to be of equal value, and the power supply is assumed to be 1.0 volt, Node 21 would be at 0.5 Volt, Node 23 would be at 0.67 Volt, and Node 25 would be at 0.33 Volt.

If a noise event occurred, e.g., where the power supply increased to 1.4 volt, then dropped back to a nominal value of 1.0 Volt, Node 21 would jump to 0.7 Volt while Node 23 would stay at 0.67 Volt. This would cause 31 OUT1 to go high, indicating an excursion event.

The analogous output would occur at 33 OUT2 is the power supply voltage drops low.

The detector has a sensitivity advantage in that the voltage is determined from a ratio of resistances, the variation in Node 21 can be set to be very close to the power supply noise variation itself.

While the invention has been described with respect to certain preferred embodiments and exemplifications, it is not intended to limit the scope of the invention thereby, but solely by the claims appended hereto.

We claim:

1. An on-chip power supply noise sensor between an on-chip power supply and ground, the sensor comprising:
a. a first resistor series between the power supply and ground; and
b. a low pass filter in parallel with the first resistor series, between the power supply and ground.

2. The on-chip power supply noise sensor of claim 1 wherein the low pass filter comprises a pair of resistors and a capacitor, the capacitor being in series with a first of said resistor between the first of said resistors and ground, and in parallel with the second of said resistors.

3. The on-chip power supply noise sensor of claim 1 comprising a pair of comparators, wherein:
a. one of said comparators has a plus input from the resistor chain and a minus input from the capacitor; and
b. the other of said comparators has a plus input from the low pass filter between the capacitor and ground, and a minus input from the resistor chain.

4. The on-chip power supply noise sensor of claim 3 adapted for receiving high frequency power overshoot and undershoot inputs on the high voltage side of the resistor chain and the low pass filter and outputting a signal from a comparator.

5. A power supply noise sensor between an on-chip power supply and ground, the sensor comprising:
a. a first resistor series between the power supply and ground; and
b. a low pass filter in parallel with the first resistor series, between the power supply and ground.

6. The power supply noise sensor of claim 5 wherein the low pass filter comprises a pair of resistors and a capacitor, the capacitor being in series with a first of said resistor between the first of said resistors and ground, and in parallel with the second of said resistors.

7. The power supply noise sensor of claim 5 comprising a pair of comparators, wherein:
a. one of said comparators has a plus input from the resistor chain and a minus input from the capacitor; and
b. the other of said comparators has a plus input from the low pass filter between the capacitor and ground, and a minus input from the resistor chain.

8. The power supply noise sensor of claim 7 adapted for receiving high frequency power overshoot and undershoot inputs on the high voltage side of the resistor chain and the low pass filter and outputting a signal from a comparator.
